(19) United States
(12) Patent Application Publication
(10) Pub. No.: US 2017/0330508 A1
(43) Pub. Date: Nov. 16, 2017

(54) PIXEL UNIT, DISPLAY PANEL, AND METHOD OF TRANSMITTING SIGNAL

(71) Applicant: SONY CORPORATION, TOKYO (JP)

(72) Inventors: KIYOHIRO SAITO, KANAGAWA (JP); HIDEYUKI SUZUKI, KANAGAWA (JP); EIICHI NAKAMOTO, KANAGAWA (JP)

(21) Appl. No.: 15/527,210

(22) PCT Filed: Oct. 29, 2015
(86) PCT No.: PCT/JP2015/080515

§ 371 Date: May 16, 2017

(30) Foreign Application Priority Data
Nov. 25, 2014 (JP) 2014-237817

(51) Int. Cl. G09G 3/3225; H01L 27/32; G09G 3/36; H01L 51/52; H01L 33/10; G02F 1/1335

(52) U.S. Cl. CPC G09G 3/3225; H01L 51/5293; H01L 33/10; H01L 27/3274; G09G 3/3648; G09G 2300/0426; G02F 2001/133614

(57) ABSTRACT

A pixel unit (P) of the invention includes a first input terminal (CKIN), a first output terminal (CKOUT), a signal generator (30), and a display device (25). The signal generator (30) is provided on a signal path extending from the first input terminal (CKIN) to the first output terminal (CKOUT). The signal generator (30) generates a second signal (CKA) on the basis of a first signal (CK) and outputs the generated second signal. The signal generator (30) generates a rising edge and a falling edge of the second signal (CKA) on the basis of one of a rising edge and a falling edge of the first signal (CK).

### TECHNICAL FIELD

The disclosure relates to a pixel unit that performs display corresponding to one pixel, a display panel using such a pixel unit, and a method of transmitting a signal.

### BACKGROUND ART

Recently, in a field of a display panel that performs image display, a display panel (an organic EL display panel) has been developed and commercialized that uses a current-driven optical device such as an organic electroluminescence (EL) device as a light-emitting device. The current-driven optical device has light-emission luminance that varies on the basis of a value of a current flowing therethrough. The organic EL device is a self light-emitting device, unlike, for example, a liquid crystal device. The organic EL device does not require a light source (a back light). The organic EL display panel therefore has features such as higher visibility of an image, lower power consumption, and higher response speed of a device, compared to a liquid crystal panel that requires the light source.

For example, PTL 1 discloses a so-called active-matrix display panel that includes a thin film transistor (TFT) in each pixel and controls light emission of an organic EL device on a pixel basis. This display panel includes a plurality of gate lines that extend in a horizontal direction, and a plurality of data lines that extend in a vertical direction. Each of the pixels is provided near an intersection of one of the gate lines and corresponding one of the data lines. Further, the pixels are selected on a line basis on the basis of signals of the gate lines, and an analog pixel voltage is written into the selected pixels.

### CITATION LIST

### Patent Literature

PTL 1: Japanese Unexamined Patent Application Publication No. 2012-32828

### SUMMARY OF THE INVENTION

It is generally desired that a display apparatus has high image quality. Specifically, for example, a high-definition display apparatus and a large-screen display apparatus may be desired in many cases. Further, a display apparatus having a high frame rate may be expected in some cases.

Accordingly, it is desirable to provide a display unit, a display panel, and a method of transmitting a signal that improve image quality.

A pixel unit according to one embodiment of the disclosure includes a first input terminal, a first output terminal, a signal generator, and a display device. The signal generator is provided on a signal path extending from the first input terminal to the first output terminal. The signal generator generates a second signal on the basis of a first signal and outputs the generated second signal. The signal generator generates a rising edge and a falling edge of the second signal on the basis of one of a rising edge and a falling edge of the first signal.

A display panel according to one embodiment of the disclosure includes a plurality of pixel units. The pixel units are sequentially coupled to each other. The pixel units each include: a first input terminal; a first output terminal; a signal generator provided on a signal path extending from the first input terminal to the first output terminal, the signal generator generating a second signal on the basis of a first signal and outputting the generated second signal; and a display device. The signal generator generates a rising edge and a falling edge of the second signal on the basis of one of a rising edge and a falling edge of the first signal.

A method of transmitting a signal according to one embodiment of the disclosure includes: causing a signal generator to cause a second signal to make a transition at timing corresponding to timing of one edge of a rising edge and a falling edge of a first signal, the signal generator being provided on a signal path extending from a first input terminal to a first output terminal of each of a plurality of signal processing units that are sequentially coupled to each other, the signal generator generating the second signal on the basis of the first signal; and causing the signal generator to cause the second signal to make another transition at timing a predetermined time period after the timing at which the second signal has made the transition, the predetermined time period corresponding to a pulse width of a pulse that starts from the one edge.

In the pixel unit, the display panel, and the method of transmitting a signal according to the embodiments of the disclosure, the second signal is generated on the basis of the first signal by the signal generator that is provided on the signal path extending from the first input terminal to the first output terminal. The rising edge and the falling edge of the generated second signal are generated on the basis of one of the rising edge and the falling edge of the first signal.

According to the pixel unit, the display panel, and the method of transmitting a signal of the embodiments of the disclosure, the rising edge and the falling edge of the second signal are generated on the basis of one of the rising edge and the falling edge of the first signal. This improves image quality. It is to be noted that the effects described above are not necessarily limitative. Any of effects described herein may be provided.

### BRIEF DESCRIPTION OF DRAWINGS

FIG. 1 is a block diagram illustrating a configuration example of a display panel according to a first embodiment of the disclosure.

FIG. 2 is an explanatory diagram illustrating a configuration example of a data signal illustrated in FIG. 1.

FIG. 3 is an explanatory diagram illustrating a configuration example of a pixel packet illustrated in FIG. 2.

FIG. 4 is an explanatory diagram illustrating a configuration example of a pilot packet illustrated in FIG. 2.

FIG. 5 is a block diagram illustrating a configuration example of a pixel illustrated in FIG. 1.

FIG. 6 is a block diagram illustrating a configuration example of a clock generator illustrated in FIG. 5.

FIG. 7 is a timing waveform chart illustrating an operation example of a clock generator illustrated in FIG. 6.

FIG. 8 is an explanatory diagram illustrating an operation example of a pixel illustrated in FIG. 5.

FIG. 9 is an explanatory diagram illustrating an operation example of a display panel illustrated in FIG. 1.

FIG. 10 is a block diagram illustrating a configuration example of a clock generator according to a modification.

FIG. 11 is a timing waveform chart illustrating an operation example of a clock generator illustrated in FIG. 10.

FIG. 12 is a block diagram illustrating a configuration example of a pixel according to another modification.

FIG. 13 is a block diagram illustrating a configuration example of a pixel according to still another modification.

FIG. 14 is a block diagram illustrating a configuration example of a display panel according to another modification.

FIG. 15 is a block diagram illustrating a configuration example of a display panel according to still another modification.

FIG. 16 is a block diagram illustrating a configuration example of a display panel according to a second embodiment.

FIG. 17 is an explanatory diagram illustrating a configuration example of a pilot packet according to the second embodiment.

FIG. 18 is an explanatory diagram illustrating a configuration example of a pixel packet according to the second embodiment.

FIG. 19 is a waveform chart illustrating an example of a data signal illustrated in FIG. 16.

FIG. 20 is a block diagram illustrating a configuration example of a pixel illustrated in FIG. 16.

FIG. 21 is a block diagram illustrating a configuration example of a signal generator illustrated in FIG. 20.

FIG. 22 is a timing waveform chart illustrating an operation example of a signal generator illustrated in FIG. 21.

FIG. 23 is an explanatory diagram illustrating a state of the signal generator illustrated in FIG. 21.

FIG. 24 is an explanatory diagram illustrating another state of the signal generator illustrated in FIG. 21.

FIG. 25 is an explanatory diagram illustrating an operation example of a pixel illustrated in FIG. 20.

### DESCRIPTION OF EMBODIMENTS

Some embodiments of the disclosure will be described below in detail with reference to the drawings. It is to be noted that the description is given in the following order.

### 1. First Embodiment

### 2. Second Embodiment

### 1. First Embodiment

### [Configuration Example]

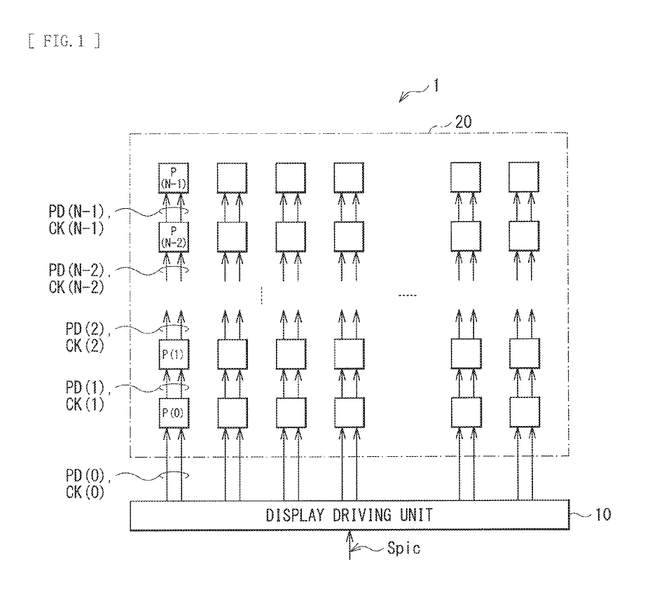

FIG. 1 illustrates a configuration example of a display panel (a display panel 1) according to a first embodiment. The display panel 1 may use a light emitting diode (LED) as a display device. It is to be noted that a method of transmitting a signal according to an embodiment of the disclosure is embodied by the present embodiment and is therefore described together. The display panel 1 may include a display driving unit 10 and a display unit 20.

The display driving unit 10 may control light emission of each of pixels P (which will be described later) in the display unit 20 on the basis of an image signal Spic. Specifically, the display driving unit 10 may supply a data signal PD and a clock signal CK to each pixel column of the pixels P in the display unit 20, and thereby control the light emission of each of the pixels P, as will be described later.

The display unit 20 may include the plurality of pixels P that are arranged in matrix. Specifically, the M-number of pixels P may be disposed in a horizontal direction (a lateral direction), and the N-number of pixels P may be disposed in a vertical direction (a longitudinal direction) in this example. The N-number of pixels P (P(0) to P(N−1)) that are disposed side by side in the vertical direction may be coupled to each other to form a daisy-chain connection. The display driving unit 10 may supply the data signal PD (PD(0)) and the clock signal CK (CK(0)) to a first pixel P(0) out of the N-number of pixels P that are coupled to each other to form the daisy-chain connection. The pixel P(0) may generate the data signal PD (PD(1)) and the clock signal CK (CK(1)) on the basis of the data signal PD(0) and the clock signal CK (0), and supply the generated signals to a following pixel P(1). The following pixel P(1) may generate the data signal PD (PD(2)) and the clock signal CK (CK(2)) on the basis of the data signal PD(1) and the clock signal CK (1), and supply the generated signals to a following pixel P(2). This may be similarly applicable to the following pixels P(2) to P(N−2). Further, the last pixel P(N−1) may receive the data signal PD (PD(N−1)) and the clock signal CK (CK(N−1)) generated by a preceding pixel P(N−2). The pixels P may be coupled to each other to form the daisy-chain connection for the data signal PD and the clock signal CK in the foregoing manner.

FIG. 2 illustrates an example of the data signal PD(0) which the display driving unit 10 generates. The data signal PD(0) may include the N-number of pixel packets PCT2 and a single pilot packet PCT1. Each of the pixel packets PCT2 (PCT2(0), PCT2(1), PCT2(2), and so on) may indicate light-emission luminance of corresponding one of the pixels P(0), P(1), P(2), and so on. Specifically, for example, the pixel packet PCT2(0) may indicate light-emission luminance of the 0 (zero)-th pixel P(0). The pixel packet PCT2(1) may indicate light-emission luminance of the first pixel P(1). The pixel packet PCT2(2) may indicate light-emission luminance of the second pixel P(2). The pilot packet PCT1 may be disposed before this series of pixel packets PCT2, and may have a predetermined data pattern as will be described later.

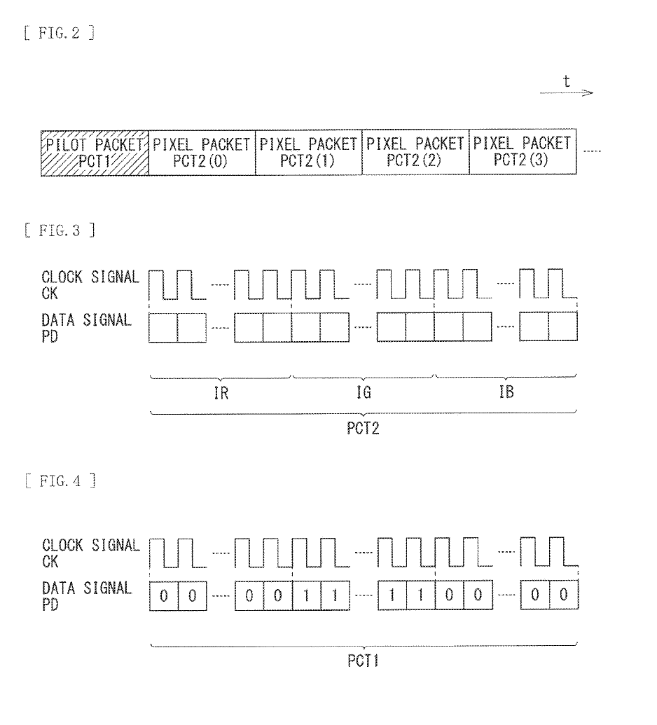

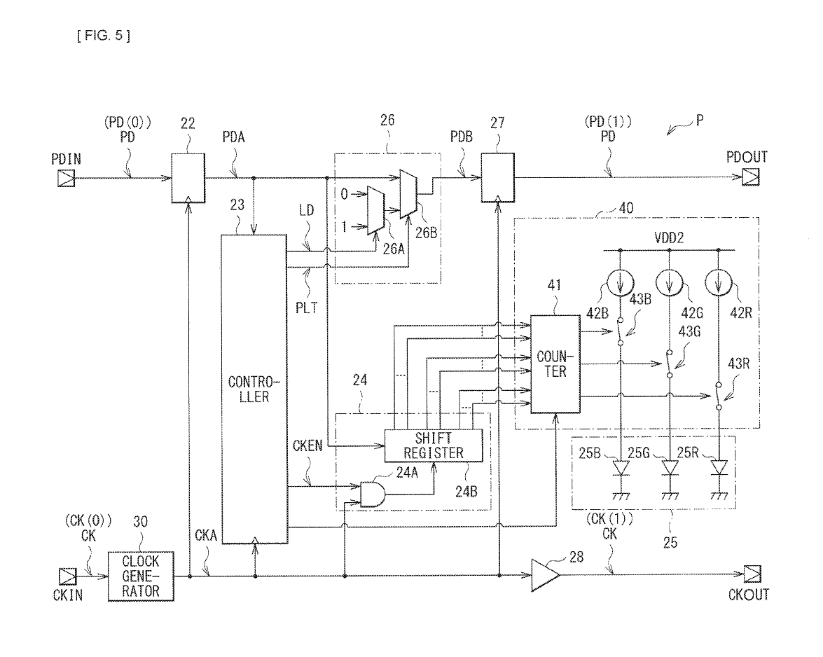

FIG. 3 illustrates a configuration example of the pixel packet PCT2. FIG. 3 illustrates a part, of the data signal PD, corresponding to the pixel packet PCT2 together with the clock signal CK. The pixel packet PCT2 may include luminance data IR, IG, and IB. The luminance data IR may indicate light-emission luminance of red (R), the luminance data IG may indicate light-emission luminance of green (G), and the luminance data IB may indicate light-emission luminance of blue (B). Each of the pieces of luminance data IR, IG, and IB may be data of 12 bits in this example. Accordingly, the pixel packet PCT2 may have data of 36 bits. It is to be noted that this is not limitative. For example, each of the pieces of luminance data IR, IG, and IB may be data of 13 bits or greater, or may be data of 11 bits or smaller. Each of the pieces of luminance data IR, IG, and IB may be so set that not all of the bits have “0”, and not all of the bits have “1”. The luminance data IR, IG, and IB may be disposed in order in the pixel packet PCT2 in this example.

FIG. 4 illustrates a configuration example of the pilot packet PCT1. The pilot packet PCT1 may have data of 36 bits as with the pixel packet PCT2 in this example. The pilot packet PCT1 may have a predetermined data pattern. Specifically, the first 12 bits in the pilot packet PCT1 may all have “0”, the following 12 bits may all have “1”, and the last 12 bits may all have “0”, in this example. In other words, out of the pilot packet PCT1, parts corresponding to respective pieces of luminance data IR and IB of the pixel packet PCT2 may all have “0”, and part corresponding to the luminance data IG may all have “1”.

Each of the pixels P may receive the data signal PD and the clock signal CK from the preceding pixel P, generate a new data signal PD and a new clock signal CK on the basis of those signals, and supply the generated signals to the following pixel P. On this occasion, each of the pixels P may determine which of the pilot packet PCT1 and the pixel packet PCT2 the received packet is on the basis of the data pattern of the data signal PD. Specifically, when the first 12 bits in the data pattern all have “0”, the following 12 bits all have “1”, and the last 12 bits all have “0”, each of the pixels P may determine that the relevant packet is the pilot packet PCT1. Further, each of the pixels P may determine that the relevant packet is the pixel packet PCT2 when the data pattern of the packet is a pattern other than the foregoing pattern. Further, each of the pixels P may read the luminance data IR, IG, and IB included in the pixel packet PCT2 following the pilot packet PCT1. Each of the pixels P may also generate a new data signal PD by replacing, with the pilot packet PCT1, a part, of the data signal PDA, related to the read pixel packet PCT2. Further, each of the pixels P may perform light emission on the basis of the read luminance data IR, IG, and IB.

FIG. 5 illustrates a configuration example of the pixel P. The pixel P may include a clock generator 30, flip-flops 22 and 27, a controller 23, a memory unit 24, a driving unit 40, a light emission unit 25, a selector unit 26, and a buffer 28. It is to be noted that the description is given below referring to the first pixel P(0) out of the N-number of pixels P that are coupled to form the daisy-chain connection for the sake of convenience in description. However, it is similarly applicable to other pixels P(1) to P(N−1).

The pixel P(0) may generate the data signal PD(1) and the clock signal CK(1) on the basis of the data signal PD(0) inputted to an input terminal PDIN and the clock signal CK(0) inputted to an input terminal CKIN. Further, the pixel P(0) may output the data signal PD(1) from an output terminal PDOUT and output the clock signal CK(1) from an output terminal CKOUT.

The clock generator 30 may generate a clock signal CKA on the basis of the clock signal CK(0).

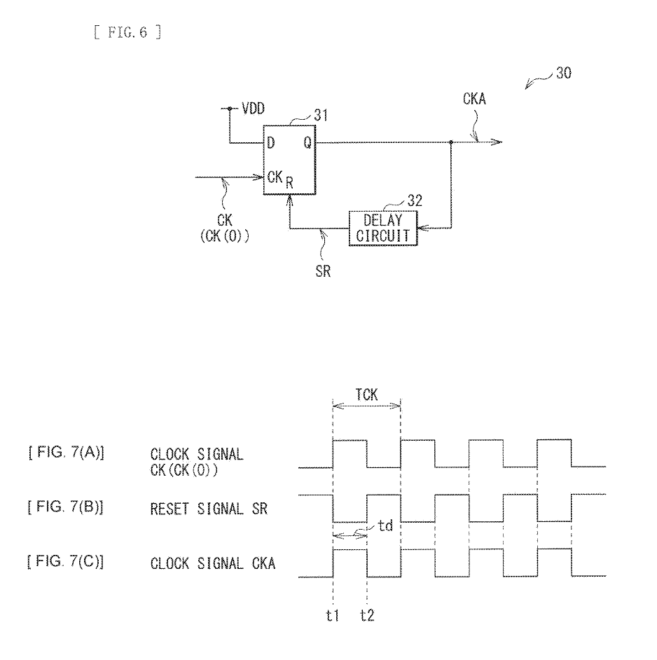

FIG. 6 illustrates a configuration example of the clock generator 30. The clock generator 30 may include a flip-flop 31 and a delay circuit 32. The flip-flop 31 may include a D flip-flop circuit. The flip-flop 31 may perform sampling of a signal at a high level (having a power source voltage VDD, in this example) on the basis of a rising edge of the clock signal CK(0), and output a result of the sampling as the clock signal CKA. The delay circuit 32 may delay the clock signal CKA by a time period “td” and output the delayed signal as a reset signal SR. The time period td may be about half the time period corresponding to one period TCK of the clock signal CK(0).

FIG. 7 illustrates an operation example of the clock generator 30. Part (A) illustrates a waveform of the clock signal CK(0), Part (B) illustrates a waveform of the reset signal SR, and Part (C) illustrates a waveform of the clock signal CKA. First, at timing t1, the clock signal CK(0) may make a transition from a low level to a high level (Part (A) of FIG. 7). The flip-flop 31 may perform sampling of a signal (at a high level) inputted to a data terminal D, at a rising timing of the clock signal CK(0). This may cause the clock signal CKA to make a transition from the low level to the high level (Part (C) of FIG. 7). The delay circuit 32 may delay this clock signal CKA by the time period td. This may cause the reset signal SR to make a transition from a low level to a high level at timing t2 which is delayed from the timing t1 by the time period td (Part (B) of FIG. 7). The flip-flop 31 may perform a reset operation on the basis of this reset signal SR. This may cause the clock signal CKA to make a transition from the high level to the low level (Part (C) of FIG. 7).

According to this configuration, the clock generator 30 may cause the clock signal CKA to make a transition from the low level to the high level in accordance with the rising of the clock signal CK (CK(0)), and cause the clock signal CKA to make a transition from the high level to the low level at the timing time period td after the rising timing of the clock signal CK (CK(0)). In other words, the clock generator 30 may generate the clock signal CKA having a duty ratio corresponding to the time period td only on the basis of the rising of the clock signal CK(CK(0)).

The flip-flop 22 (FIG. 5) may include a D flip-flop circuit, for example. The flip-flop 22 may perform sampling of the data signal PD(0) on the basis of the clock signal CKA, and output a result thereof as the data signal PDA.

The controller 23 may serve as a state machine that sets a state of the pixel P(0) and generates signals LD, PLT, and CKEN, on the basis of the data signal PDA and the clock signal CKA. The signals LD and PLT may each be a signal for replacing the pixel packet PCT2 included in the data signal PDA with the pilot packet PCT1. Specifically, the signal LD may correspond to a data pattern of the pilot packet PCT1. The signal PLT may be a control signal that indicates timing for this replacement. Further, the signal CKEN may be a control signal that indicates timing for storing the luminance data IR, IG, and IB in the memory unit 24. Further, the controller 23 may also have a function of supplying the control signal to the driving unit 40.

The memory unit 24 may store the luminance data IR, IG, and IB. The memory unit 24 may include an AND circuit 24A and a shift register 24B. The AND circuit 24A may determine a logical conjunction of the signal CKEN and the clock signal CKA. The shift register 24B may be a 36-bit shift register in this example. The data signal PDA may be inputted to a data input terminal of the shift register 24B, and an output signal of the AND circuit 24A may be inputted to a clock input terminal of the shift register 24B.

According to this configuration, the memory unit 24 may store data included in the data signal PDA in a period in which the signal CKEN is “1”. The signal CKEN may be “1” in a period in which the data signal PDA indicates the pixel packet PCT2 following the pilot packet PCT1, and be “0” in other periods. Accordingly, the AND circuit 24A may supply the clock signal to the shift register 24B in the period in which the data signal PDA indicates the pixel packet PCT2 following the pilot packet PCT1. Further, the shift register 24B may store the luminance data IR, IG, and IB corresponding to 36 bits related to that pixel packet PCT2. On this occasion, part corresponding to the last 12 bits of the shift register 24B may store the luminance data IR, part corresponding to the 12 bits around the middle may store the luminance data IG, and part corresponding to the first 12 bits may store the luminance data IB.

The driving unit 40 may drive the light emission unit 25 on the basis of the luminance data IR, IG, and IB stored in the memory unit 24. The driving unit 40 may include a counter 41, current sources 42R, 42G, and 42B, and switches 43R, 43G, and 43B.

The counter 41 may use the control signal (a counter clock signal) supplied from the controller 23 as a reference and count clock pulses thereof. The counter 41 may thereby generate pulse signals having respective pulse widths based on the luminance data IR, IG, and IB stored in the memory unit 24. Specifically, the counter 41 may include unillustrated count comparator circuits 41R, 41G, and 41B, for example. The count comparator circuit 41R may compare a count value corresponding to the luminance data IR with a count value of the clock pulse. The count comparator circuit 41R may thereby generate a pulse signal having a pulse width based on the luminance data IR. This may be similarly applicable to the count comparator circuits 41G and 41B.

The current sources 42R, 42G, and 42B may each generate a constant drive current. The switches 43R, 43G, and 43B may be turned on and off on the basis of the pulse signal supplied from the counter 41.

The light emission unit 25 may perform light emission on the basis of the drive current supplied from the driving unit 40. The light emission unit 25 may include light-emitting devices 25R, 25G, and 25B. The light-emitting devices 25R, 25G, and 25B each may include an LED, and may output light of red (R), green (G), and blue (B), respectively.

According to this configuration, first, the counter 41 may generate each of the pulse signals having the respective pulse widths based on the luminance data IR, IG, and IB stored in the memory unit 24. Further, the switch 43R may be turned on or off on the basis of the pulse signal having the pulse width based on the luminance data IR, and supply the drive current generated by the current source 42R to the light-emitting device 25R. The light-emitting device 25R may output red (R) light on the basis of the supplied drive current. Similarly, the switch 43G may be turned on or off on the basis of the pulse signal having the pulse width based on the luminance data IG, and supply the drive current generated by the current source 42G to the light-emitting device 25G. The light-emitting device 25G may output green (G) light on the basis of the supplied drive current. Further, the switch 43B may be turned on or off on the basis of the pulse signal having the pulse width based on the luminance data IB, and supply the drive current generated by the current source 42B to the light-emitting device 25B. The light-emitting device 25B may output blue (B) light on the basis of the supplied drive current. The light-emitting devices 25R, 25G, and 25B may thus emit light at light-emission luminance (luminance×time) based on a time width of light emission.

The selector unit 26 may generate the data signal PDB on the basis of the data signal PDA and the signals LD and PLT. The selector unit 26 may include selectors 26A and 26B. “0” may be inputted to a first input terminal of the selector 26A, “1” may be inputted to a second input terminal thereof, and the signal LD may be inputted to a control input terminal thereof. This selector 26A may output “0” inputted to the first input terminal when the signal LD is “0”, and output “1” inputted to the second input terminal when the signal LD is “1”. The data signal PDA may be inputted to a first input terminal of the selector 26B, an output signal of the selector 26A may be inputted to a second input terminal thereof, and the signal PLT may be inputted to a control input terminal thereof. This selector 26B may output the data signal PDA inputted to the first input terminal when the signal PLT is “0”, and output the output signal of the selector 26A inputted to the second input terminal when the signal PLT is “1”. The selector unit 26 may supply an output signal of this selector 26B to the flip-flop 27 as the data signal PDB.

According to this configuration, the selector unit 26 may output, as the data signal PDB, the data signal PDA as it is in the period in which the signal PLT is “0”, and output, as the data signal PDB, the signal (the output signal of the selector 26A) based on the signal LD in the period in which the signal PLT is “1”. This signal PLT may be “1” in the period in which the data signal PDA indicates the pixel packet PCT2 following the pilot packet PCT1, and may be “0” in other periods. In other words, the selector unit 26 may generate the data signal PDB by replacing, with the pilot packet PCT1, part, of the data signal PDA, related to the pixel packet PCT2 read by the memory unit 24.

The flip-flop 27 may include a D flip-flop circuit, for example. The flip-flop 27 may perform sampling of the data signal PDB on the basis of the clock signal CKA, and output a result thereof as the data signal PD(1).

The buffer 28 may perform waveform shaping on the clock signal CKA, and output the resulting signal as the clock signal CK(1).

In this example, the input terminal CKIN may correspond to one specific example of a “first input terminal” of the disclosure. The output terminal CKOUT may correspond to one specific example of a “first output terminal” of the disclosure. The input terminal PDIN may correspond to one specific example of a “second input terminal” of the disclosure. The output terminal PDOUT may correspond to one specific example of a “second output terminal” of the disclosure. The clock generator 30 may correspond to one specific example of a “signal generator” of the disclosure. The controller 23 and the selector unit 26 may correspond to one specific example of a “controller” of the disclosure.

### [Operation and Working]

Next, operations and workings of the display panel 1 according to the present embodiment are described.

### [Outline of Overall Operation]

First, an outline of an overall operation of the display panel 1 is described with reference to FIG. 1, etc. The display driving unit 10 may control light emission of each of the pixels P in the display unit 20 on the basis of the image signal Spic. Specifically, the display driving unit 10 may supply the data signal PD and the clock signal CK to each of the pixel columns of the pixels P in the display unit 20. Each of the pixels P may receive the data signal PD and the clock signal CK from the preceding one. Each of the pixels P may generate a new data signal PD and a new clock signal CK on the basis of them, and supply the generated signals to the following pixel P. On this occasion, each of the pixels P may determine which of the pilot packet PCT1 and the pixel packet PCT2 the received packet is on the basis of the data pattern of the data signal PD. Further, each of the pixels P may read the luminance data IR, IG, and IB included in the pixel packet PCT2 following the pilot packet PCT1, and generate the new data signal PD by replacing the read part related to the pixel packet PCT2 with the pilot packet PCT1. Further, each of the pixels P may perform light emission on the basis of the read luminance data IR, IG, and IB.

### [Detailed Operation]

Next, an operation of reading the luminance data IR, IG, and IB by the pixel P is described in detail.

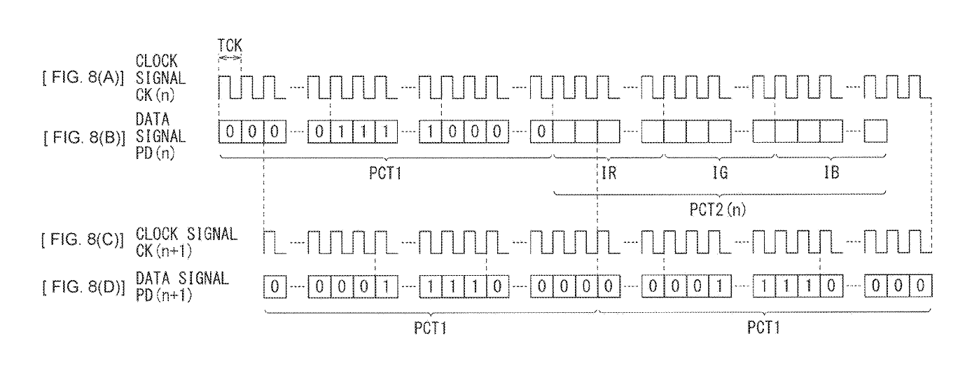

FIG. 8 illustrates the operation of reading the luminance data IR, IG, and IB by the n-th pixel P(n). Parts (A) and (B) illustrate the clock signal CK(n) and the data signal PD(n) that are inputted to the pixel P(n), respectively. Parts (C) and (D) illustrate the clock signal CK(n+1) and the data signal PD(n+1) that are outputted from the pixel P(n), respectively.

The pixel P(n−1) preceding the pixel P(n) may supply the pixel P(n) with the data signal PD(n) together with the clock signal CK(n). The data signal PD(n) may include the pilot packet PCT1 and the following pixel packet PCT2(n) (Parts (A) and (B) of FIG. 8).

In the pixel P(n), the clock generator 30 may generate the clock signal CKA on the basis of the clock signal CK(n) as illustrated in FIG. 7. Further, the flip-flop 22 may perform sampling of the data signal PD(n) on the basis of the clock signal CKA, and generate the data signal PDA. The controller 23 may determine that the pixel packet PCT2(n) is supplied after the pilot packet PCT1 on the basis of the data pattern of the data signal PDA.

In a period in which the data signal PDA indicates the pilot packet PCT1, the controller 23 may supply the signals LD and PLT to the selector unit 26, and the selector unit 26 may select the data signal PDA and output the selected data signal PDA as the data signal PDB. Further, the flip-flop 27 may perform sampling of this data signal PDB on the basis of the clock signal CKA, thereby generating the data signal PD(n+1) (Part (D) of FIG. 8).

Further, in a period in which the data signal PDA indicates the pixel packet PCT2(n) following the pilot packet PCT1, the controller 23 may supply the signal CKEN to the memory unit 24, and the memory unit 24 may read the luminance data IR, IG, and IB included in the foregoing pixel packet PCT2(n). In this period, the controller 23 may also supply the signals LD and PLT to the selector unit 26, and the selector unit 26 may replace, with the pilot packet PCT1, the pixel packet PCT2(n) included in the data signal PDA, and output the resultant as the data signal PDB. Further, the flip-flop 27 may perform sampling of this data signal PDB on the basis of the clock signal CKA, thereby generating the data signal PD(n+1) (Part (D) of FIG. 8).

The pixel P(n) may thus generate the data signal PD(n+1), and output the generated data signal PD(n+1) together with the clock signal CK(n+1) (Parts (C) and (D) of FIG. 8). On this occasion, the data signal PD(n+1) may be delayed by an amount corresponding to two clocks from the data signal PD(n), since the pixel P(n) may include the two flip-flops 22 and 27 as illustrated in FIG. 5. It is to be noted that the amount of delay may depend on the configuration of the pixel P(n). Therefore, the amount of delay may correspond to one clock or three or more clocks in some cases where the pixel P(n) has a configuration different from the configuration illustrated in FIG. 5.

Further, the driving unit 40 in the pixel P(n) may drive the light emission unit 25 on the basis of the luminance data IR, IG, and IB stored in the memory unit 24. This may cause the respective light-emitting devices 25R, 25G, and 25B in the light emission unit 25 to emit light for time periods based on the luminance data IR, IG, and IB, respectively.

FIG. 9 illustrates an operation of the display panel 1. The display driving unit 10 may generate the data signal PD(0) in which the pilot packet PCT1, the pixel packets PCT2(0), PCT2(1), PCT2(2), PCT2(3), PCT2(4), and so on are provided in this order.

The 0th (zeroth) pixel P(0) may receive the pilot packet PCT1 and the following pixel packet PCT2(0) by means of the data signal PD(0). Further, the pixel P(0) may read the luminance data IR, IG, and IB included in this pixel packet PCT2(0), and generate the data signal PD(1) by replacing, with the pilot packet PCT1, part, of the data signal PD(0), related to the pixel packet PCT2(0).

Similarly, the 1st (first) pixel P(1) may receive the two pilot packets PCT1 and the following pixel packet PCT2(1) by means of the data signal PD(1). Further, the pixel P(1) may read the luminance data IR, IG, and IB included in this pixel packet PCT2(1), and generate the data signal PD(2) by replacing, with the pilot packet PCT1, part, of the data signal PD(1), related to the pixel packet PCT2(1).

Similarly, the 2nd (second) pixel P(2) may receive the three pilot packets PCT1 and the following pixel packet PCT2(2) by means of the data signal PD(2). Further, the pixel P(2) may read the luminance data IR, IG, and IB included in this pixel packet PCT2(2), and generate the data signal PD(3) by replacing, with the pilot packet PCT1, part, of the data signal PD(2), related to the pixel packet PCT2(2).

This may be similarly applicable to the 3rd (third) pixel P and the following pixels P.

The pixels P may be thus coupled to each other to form a daisy-chain connection in the display panel 1. Accordingly, each of the pixels P may receive the data signal PD and the clock signal CK from the preceding pixel P, and generate the new data signal PD and the new clock signal CK on the basis of the received signals to supply the generated signals to the following pixel P. Further, each of the pixels P may read, from the data signal PD, the luminance data IR, IG, and IB related to that pixel P, and emit light at light-emission luminance based on the read luminance data IR, IG, and IB. The pixels P may be thus coupled to each other to form the daisy-chain connection in the display panel 1. It is therefore possible to improve image quality.

Specifically, for example, in the display panel disclosed in PTL 1, the driving unit drives the respective pixels via, for example, the gate lines and the data lines. These gate lines and data lines are coupled to a plurality of pixels corresponding to one pixel column or a plurality of pixels corresponding to one pixel row. In other words, these gate lines and data lines are global wirings. Accordingly, for example, in a case of achieving a large-screen display panel, the lengths of these wirings are increased, which results in an increase in resistance, parasitic capacitance, etc. of the wirings. This may prevent the respective pixels from being driven sufficiently. Further, for example, in a case of achieving a high-definition display panel, it is necessary to drive more lines in each frame period. Therefore, time allocated for one horizontal period (1 H) may be reduced. This may prevent the respective pixels from being driven sufficiently. Further, for example, in a case of increasing a frame rate, time allocated for one horizontal period (1 H) may be reduced. This may prevent the respective pixels from being driven sufficiently.

In contrast, in the display panel 1 according to the present embodiment, the pixels P may be coupled to each other to form the daisy-chain connection. In other words, each of the pixels P may drive the following pixel P not by means of the foregoing global wirings but by means of a local wiring between the pixels P. Accordingly, each of the pixels P may be able to drive the following pixel P relatively easily via such short wirings. This allows for achievement of a large-screen display panel. Moreover, owing to the short wirings, each of the pixels P may be able to increase transfer speed of the data signal PD relatively easily. It is therefore possible to achieve a high-definition display panel, a high-frame-rate display panel, etc.

Moreover, since the pixels P are thus coupled to each other to form the daisy-chain connection, the configuration of the display panel 1 is simplified. Specifically, for example, the display panel disclosed in PTL 1 includes a plurality of gate lines extending in a horizontal direction (a lateral direction), a plurality of data lines extending in a vertical direction (a longitudinal direction), a so-called gate driver coupled to the gate lines, and a so-called data driver coupled to the data lines. This may make the configuration of the display panel complicated. In contrast, the display panel 1 according to the present embodiment may include the pixels P that are coupled to each other to form the daisy-chain connection. Accordingly, it is sufficient that only the wiring between the pixels P extending in the vertical direction (the longitudinal direction) and the display driving unit 10 are provided as illustrated in FIG. 1. This allows for absence of wirings extending in the horizontal direction (the lateral direction), a driving unit that drives those wirings, etc. It is therefore possible to simplify the configuration of the display panel 1.

Moreover, the display panel 1 may generate the clock signal CKA having the duty ratio corresponding to the time period td on the basis of only the rising of the clock signal CK. This reduces a possibility of degrading the waveform of the clock signal CK due to transmission. Specifically, for example, in a case where each of the pixels P does not include the clock generator 30 and includes only the buffer 28, the duty ratio of the clock signal CK may be varied after passing through a plurality of buffers, for example. Such a phenomenon may occur, for example, in a case where the transistors included in the buffers 28 involve variations in characteristics. In a case where the duty ratio is varied in such a manner, transmission of the clocks may not be performed properly, or the timing of the sampling performed by each of the flip-flops 22 and 27 in the pixels P may be shifted, for example. This may result in an improper operation. In contrast, the display panel 1 according to the present embodiment may generate the clock signal CKA having the duty ratio corresponding to the time period td on the basis of only the rising of the clock signal CK. It is therefore possible to reduce the possibility of varying the duty ratio of the clock signal CK due to transmission.

Moreover, the display panel 1 may thus maintain the duty ratio of the clock signal CK at a substantially-constant ratio. This allows for an increase in the number of pixels P that are coupled to each other to form the daisy-chain connection. It is therefore possible to achieve, for example, a high-definition display panel.

Moreover, the display panel 1 may control the light emission of each of the pixels P by means of digital signals (the data signal PD and the clock signal CK). This reduces an influence of a noise on image quality. For example, the display panel disclosed in PTL 1 uses an analog signal. This may degrade image quality due to a noise. Further, an influence of a noise on image quality may be greater especially in a display panel having a large screen, high definition, or a high frame rate. In contrast, the display panel 1 according to the present embodiment may use a digital signal. It is therefore possible to reduce the influence of the noise on image quality.

Moreover, such use of the digital signals reduces radiation. Specifically, for example, in a case where an analog signal is used, the signal amplitude may be increased in terms of expression of gradation, resistance to a noise, etc. The radiation may be increased in this case. In contrast, the display panel 1 according to the present embodiment may use digital signals. This allows for a decrease in signal amplitude. It is therefore possible to reduce radiation.

Moreover, in the display panel 1, each of the pixels P may include the flip-flops 22, 27, and 31, the buffer 28, etc. This allows for a decrease in signal amplitudes of the data signal PD and the clock signal CK. Specifically, for example, absence of the flip-flops 22, 27, and 31, the buffer 28, etc. may result in attenuation of signal amplitude in accordance with an increasing distance from the display driving unit. In this case, the display driving unit may be necessary to generate the data signal PD with great signal amplitude. In contrast, the display panel 1 may maintain the signal amplitude by performing waveform shaping on the data signal PD and the clock signal CK each time the signals pass through the pixel P. In other words, it is possible to reduce a possibility of attenuation of signal amplitude. This allows for a decrease in signal amplitudes of the data signal PD and the clock signal CK. Accordingly, it is possible to reduce the radiation described above and decrease the power source voltage, resulting in reduction in power consumption.

Moreover, in the display panel 1, each of the pixels P may include the memory unit 24. It is therefore not necessary to perform data transmission, for example, in a case of displaying a still image. This reduces power consumption.

Moreover, in the display panel 1, each of the pixels P may include the flip-flops 22 and 27 that each perform sampling of the data signal PD on the basis of the clock signal CK. It is therefore possible to maintain a relative phase relationship between the data signal PD and the clock signal CK.

Moreover, in the display panel 1, each of the pixels P may replace, with the pilot packet PCT1, the part, of the data signal PD, related to the read pixel packet PCT2. This allows for a simple configuration. Specifically, for example, in a case where an address is given to each of the pixels P and the address of the pixel P that is to read the luminance data IR, IG, and IB is included in the pixel packet, it is necessary to provide a memory for storing the address in each of the pixels P or to perform a control operation of giving an address to each of the pixels P, which makes the configuration complicated. In contrast, in the display panel 1, each of the pixels P may replace, with the pilot packet PCT1, the part, of the data signal PD, related to the red pixel packet PCT2. This allows each of the pixels P to easily determine the pixel packet PCT2 from which the luminance data IR, IG, and IB is to be read. Specifically, for example, it may not be necessary for each of the pixels P to store an address. It is therefore possible to achieve a simple configuration.

### [Effect]

As described above, according to the present embodiment, each of the pixels may generate a new clock signal on the basis of only the rising of the clock signal. It is therefore possible to reduce a possibility of degrading the waveform of the clock signal due to transmission.

Moreover, according to the present embodiment, each of the pixels may replace, with the pilot packet, the part, of the data signal, related to the read pixel packet. It is therefore possible to achieve a simple configuration.

### [Modification 1-1]

In the foregoing embodiment, the clock signal CKA may be generated on the basis of only the rising of the clock signal CK. However, this is not limitative. A clock generator 30A according to the present modification is described below in detail.

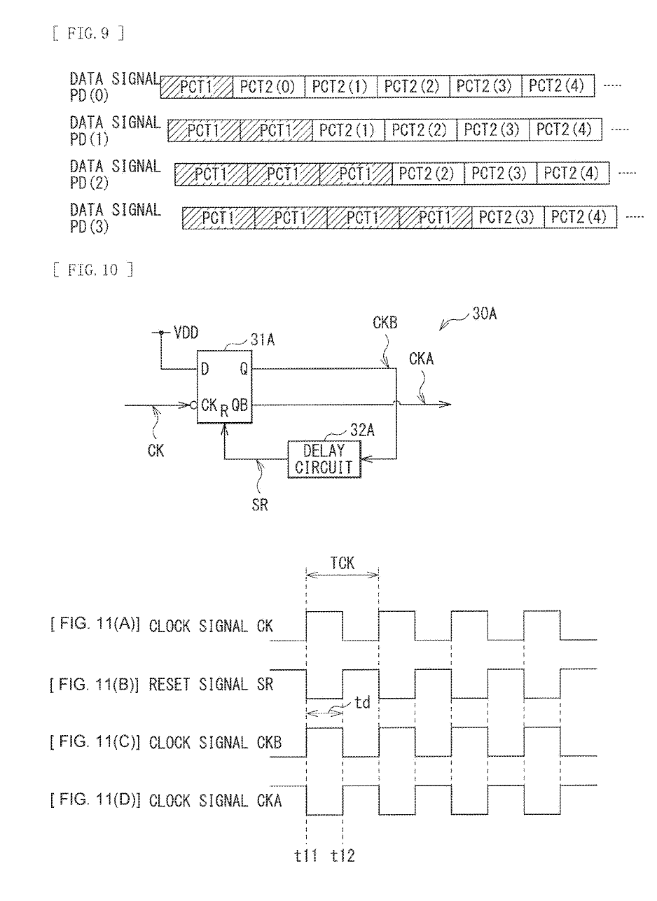

FIG. 10 illustrates a configuration example of the clock generator 30A. The clock generator 30A may include a flip-flop 31A. The flip-flop 31A may include a D flip-flop circuit. The flip-flop 31A may perform sampling of a signal at a high level (having a power source voltage VDD, in this example) on the basis of a falling edge of the clock signal CK, and output a result of the sampling as the clock signal CKB. The flip-flop 31A may also output an inverted signal of the clock signal CKB as the clock signal CKA. A delay circuit 32A may delay the clock signal CKB by a time period “td” and output the delayed signal as the reset signal SR. The time period td may be about half the time period corresponding to one period TCK of the clock signal CK.

FIG. 11 illustrates an operation example of the clock generator 30A. Part (A) illustrates a waveform of the clock signal CK, Part (B) illustrates a waveform of the reset signal SR, Part (C) illustrates a waveform of the clock signal CKB, and Part (D) illustrates a waveform of the clock signal CKA. First, at timing t11, the clock signal CK may make a transition from a high level to a low level (Part (A) of FIG. 11). The flip-flop 31A may perform sampling of a signal (at a high level) inputted to a data terminal D, at a falling timing of this clock signal CK. This may cause the clock signal CKB to make a transition from a low level to a high level (Part (C) of FIG. 11), and cause the clock signal CKA to make a transition from a high level to a low level (Part (D) of FIG. 11). The delay circuit 32A may delay this clock signal CKB by the time period td. This may cause the reset signal SR to make a transition from a low level to a high level at timing t12 which is delayed from the timing t11 by the time period td (Part (B) of FIG. 11). The flip-flop 31A may perform a reset operation on the basis of this reset signal SR. This may cause the clock signal CKB to make a transition from the high level to the low level (Part (C) of FIG. 11), and cause the clock signal CKA to make a transition from the low level to the high level (Part (D) of FIG. 11).

According to this configuration, the clock generator 30A may cause the clock signal CKA to make a transition from the high level to the low level in accordance with the falling of the clock signal CK, and cause the clock signal CKA to make a transition from the low level to the high level at the timing time period td after the falling timing of the clock signal CK. In other words, the clock generator 30A may generate the clock signal CKA having a duty ratio corresponding to the time period td on the basis of only the falling of the clock signal CK.

It is to be noted that the configuration of the clock generator is not limited to the configuration illustrated in each of FIGS. 6 and 10. The clock generator may have various circuit configurations. Specifically, the clock generator may include the D flip-flop circuit, for example. However, this is not limitative. For example, the clock generator may include an SR latch circuit.

### [Modification 1-2]

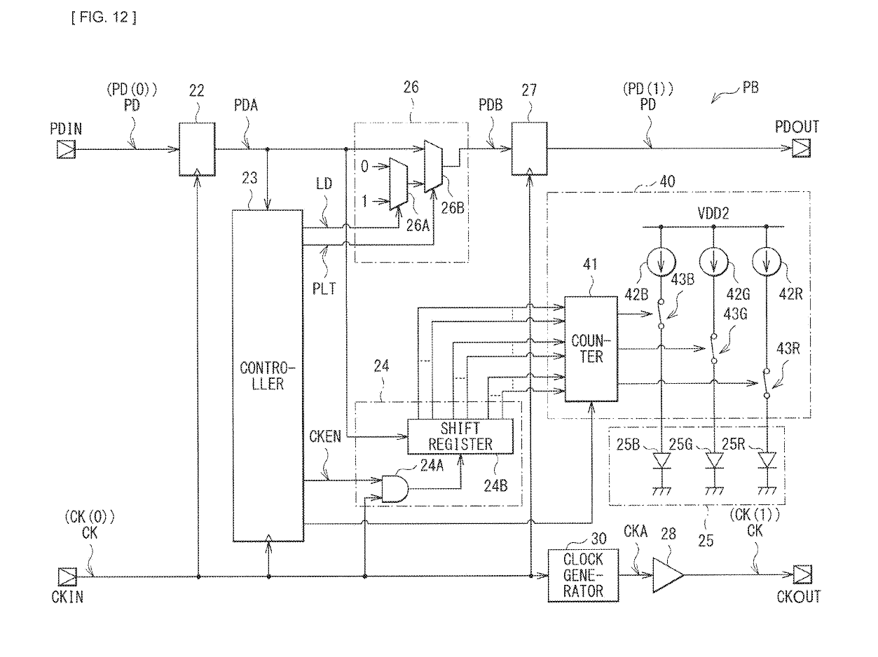

The foregoing embodiment has a configuration in which the flip-flops 22 and 27, the controller 23, and the memory unit 24 operate on the basis of the clock signal CKA generated by the clock generator 30. However, this is not limitative. For example, a configuration in which the flip-flops 22 and 27, the controller 23, and the memory unit 24 operate on the basis of the clock signal CK(CK(0)) may be provided as a pixel PB illustrated in FIG. 12.

### [Modification 1-3]

According to the foregoing embodiment, the driving unit 40 may include the counter 41. However, this is not limitative. Alternatively, for example, the driving unit may include a digital analog converter (DAC). A pixel PC according to the present modification is described below in detail.

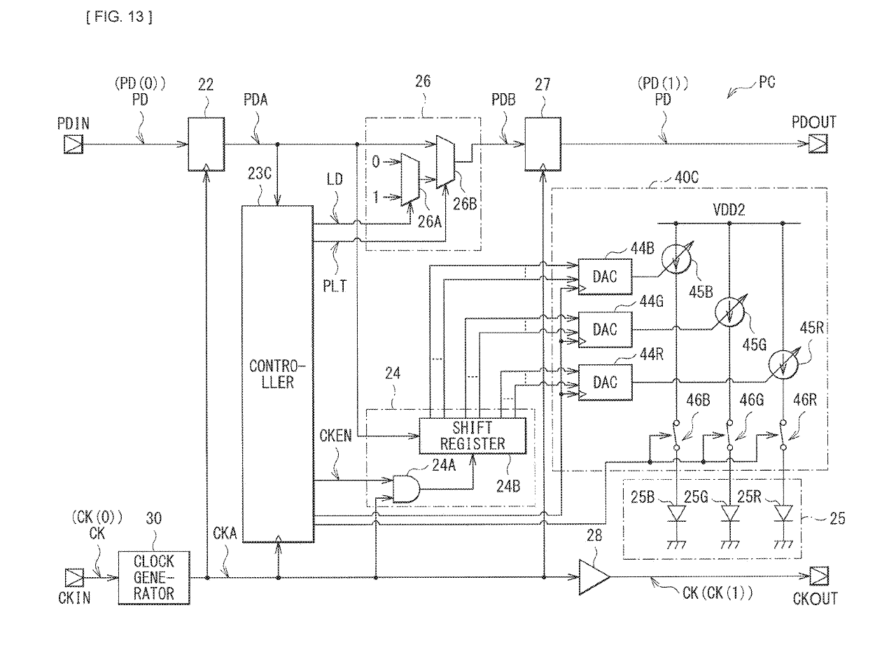

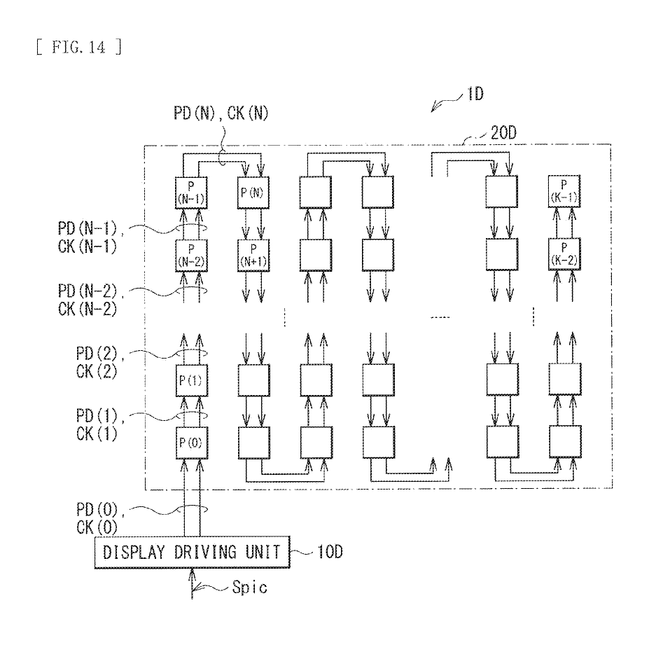

FIG. 13 illustrates a configuration example of the pixel PC. This pixel PC may include a controller 23C and a driving unit 40C. The controller 23C may function as a state machine as with the controller 23 according to the foregoing embodiment, and supply a control signal to the driving unit 40C. The driving unit 40C may include DACs 44R, 44G, and 44B and variable current sources 45R, 45G, and 45B. The DACs 44R, 44G, and 44B may convert the respective luminance data IR, IG, and IB (digital codes) into analog voltages on the basis of the control signal supplied from the controller 23C, respectively. The variable current sources 45R, 45G, and 45B may generate respective drive currents in accordance with the analog voltages supplied from the respective DACs 44R, 44G, and 44B.

According to this configuration, for example, the DAC 44R may generate the analog voltage on the basis of the luminance data IR. Further, the variable current source 45R may generate the drive current on the basis of the generated analog voltage, and supply the generated drive current to the light-emitting device 25R in the light emission unit 25 via a switch 46R. The light-emitting device 25R may emit light at light emission luminance in accordance with the supplied drive current. Accordingly, the pixel PC may be able to vary the light emission luminance (luminance×time) by varying the luminance. Specifically, the pixel P according to the foregoing embodiment may vary the light emission luminance (luminance×time) by varying a width of time period during which light emission is performed. However, the pixel PC according to the present modification may be able to vary the light emission luminance (luminance×time) by varying the luminance.

It is to be noted that ON-OFF control of each of the switches 46R, 46G, and 46B may be performed by the control signal supplied from the controller 23C. This allows the pixel PC to adjust the light emission luminance while maintaining the balance of the light emission luminance between red (R), green (G), and blue (B).

### [Modification 1-4]

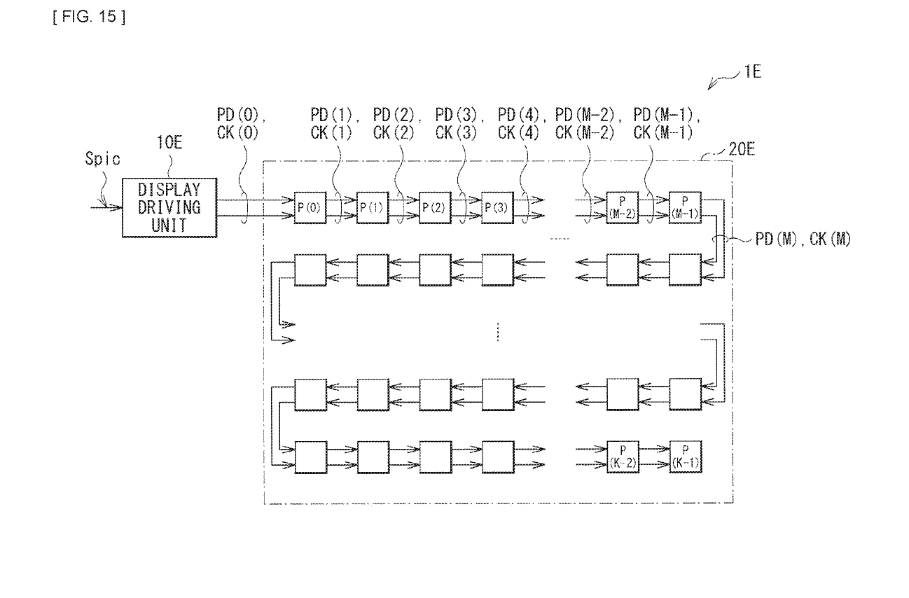

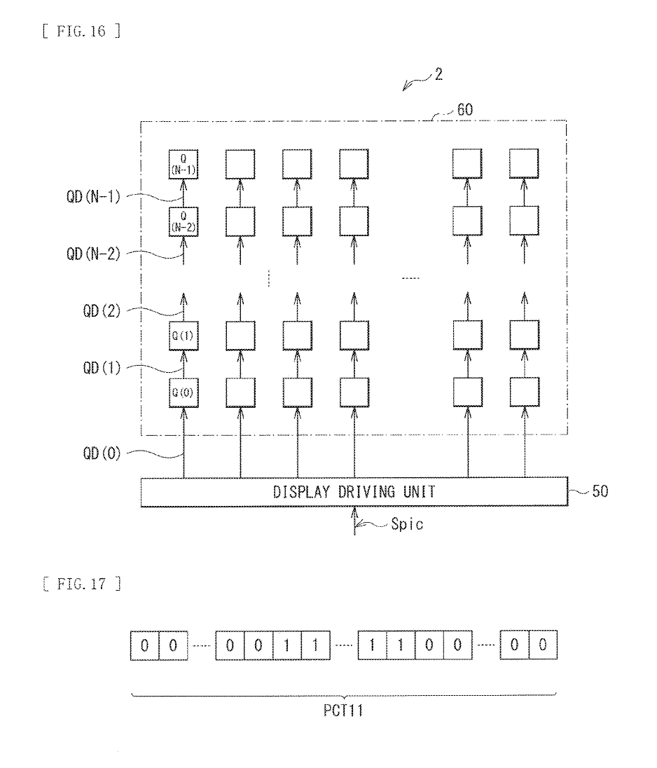

According to the foregoing embodiment, the N-number of pixels P (P(0) to P(N−1)) that are disposed side by side in the vertical direction may be coupled to each other to form the daisy-chain connection. However, this is not limitative. For example, the M-number of pixels P that are disposed side by side in the horizontal direction may be coupled to each other to form a daisy-chain connection. Alternatively, all of the (the K-number of) pixels P may be coupled to each other to form a daisy-chain connection as a display panel 1D illustrated in FIG. 14 and a display panel 1E illustrated in FIG. 15, for example. In the display panel 1D, the N-number of pixels P that are disposed side by side in the vertical direction may be coupled to each other to form the daisy-chain connection, and the output signal of the last one in each pixel column may be supplied to the first one in the adjacent column. All of the pixels P may be thus coupled to each other to form the daisy-chain connection. In the display panel 1E, the M-number of pixels P that are disposed side by side in the horizontal direction may be coupled to each other to form the daisy-chain connection, and the output signal of the last one in each pixel row may be supplied to the first one in the adjacent row. All of the pixels P may be thus coupled to each other to form the daisy-chain connection.

### [Other Modifications]

Moreover, two or more of these modifications may be applied in combination.

### 2. Second Embodiment

Next, a display panel 2 according to a second embodiment is described. According to the present embodiment, each of the pixels may transmit the data signal and the clock signal to the following pixel by means of a single signal. It is to be noted that a component substantially the same as that of the display panel 1 according to the foregoing first embodiment is denoted with the same numeral and will not be described further where appropriate.

FIG. 16 illustrates a configuration example of the display panel 2. The display panel 2 may include a display driving unit 50 and a display unit 60.

The display driving unit 50 may control light emission of each of pixels Q (which will be described later) in the display unit 60 on the basis of the image signal Spic. Specifically, the display driving unit 50 may supply a data signal QD to each pixel column of the pixels Q in the display unit 60, and thereby control the light emission of each of the pixels Q, as will be described later.

The display unit 60 may include the plurality of pixels Q that are arranged in matrix. The N-number of pixels Q (Q(0) to Q(N−1)) that are disposed side by side in the vertical direction may be coupled to each other to form a daisy-chain connection. The display driving unit 50 may supply the data signal QD (QD(0)) to a first pixel Q(0) out of the N-number of pixels Q that are coupled to each other to form the daisy-chain connection. The pixel Q(0) may generate the data signal QD (QD(1)) on the basis of the data signal QD(0), and supply the generated signal to a following pixel Q(1). The following pixel Q(1) may generate the data signal QD (QD(2)) on the basis of the data signal QD(1), and supply the generated signal to a following pixel Q(2). This may be similarly applicable to the following pixels Q(2) to Q(N−2). Further, the last pixel Q(N−1) may receive the data signal QD (QD(N−1)) generated by a preceding pixel Q(N−2).

The data signal QD may include a pilot packet PCT11 and a pixel packet PCT12 as with the data signal PD (FIG. 2) according to the first embodiment.

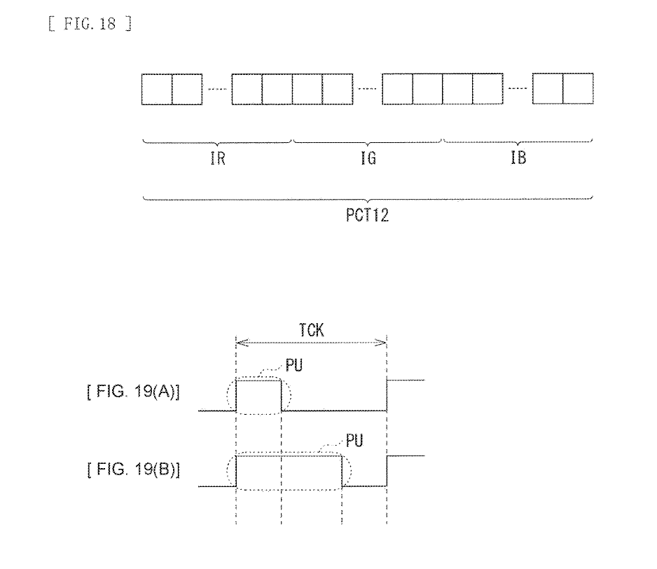

FIG. 17 illustrates a configuration example of the pilot packet PCT11. FIG. 18 illustrates a configuration example of the pixel packet PCT12. The pilot packet PCT11 may include a predetermined data pattern as with the pilot packet PCT1 according to the first embodiment. The pixel packet PCT12 may include luminance data IR, IG, and IB as with the pixel packet PCT2 according to the first embodiment.

The data signal QD may transmit the pilot packet PCT11 and the pixel packet PCT12 described above to each of the pixels Q. This data signal QD may indicate data (“0” or “1”) by varying a pulse width as described below.

FIG. 19 illustrates a waveform of the data signal QD. Part (A) illustrates the waveform in a case of indicating the data “0”. Part (B) illustrates the waveform in a case of indicating the data “1”. The data signal QD may include a single pulse PU in each period TCK. In this example, the width of the pulse PU of the data signal QD may be smaller than half the time corresponding to the period TCK in the case of indicating “0”, and may be greater than half the time corresponding to the period TCK in the case of indicating “1”.

As described above, the data signal QD may indicate “0” or “1” by varying the pulse width. This makes it possible for the display panel 2 to use the data signal QD as the data signal and to use the data signal QD also as the clock signal.

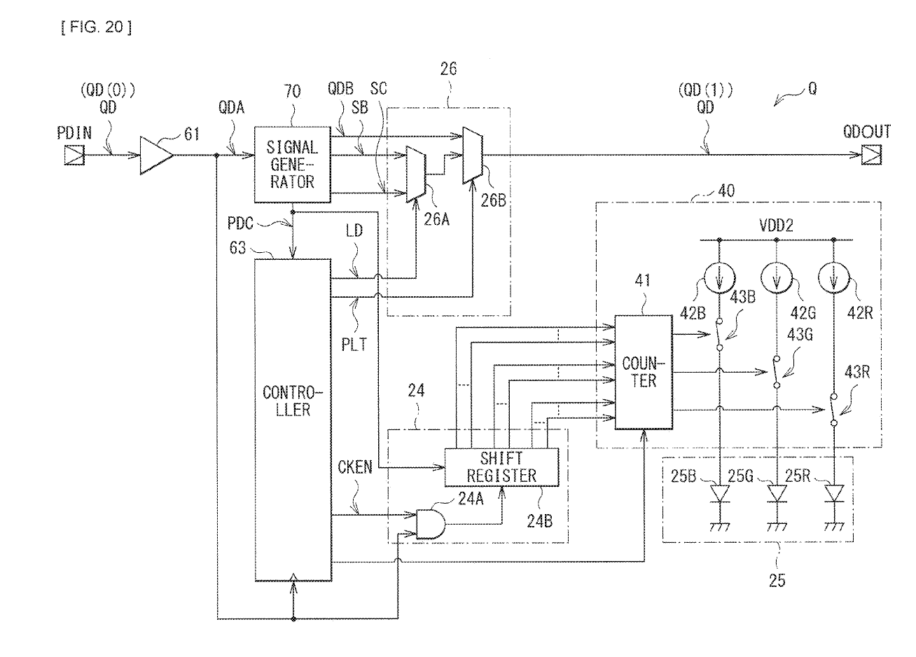

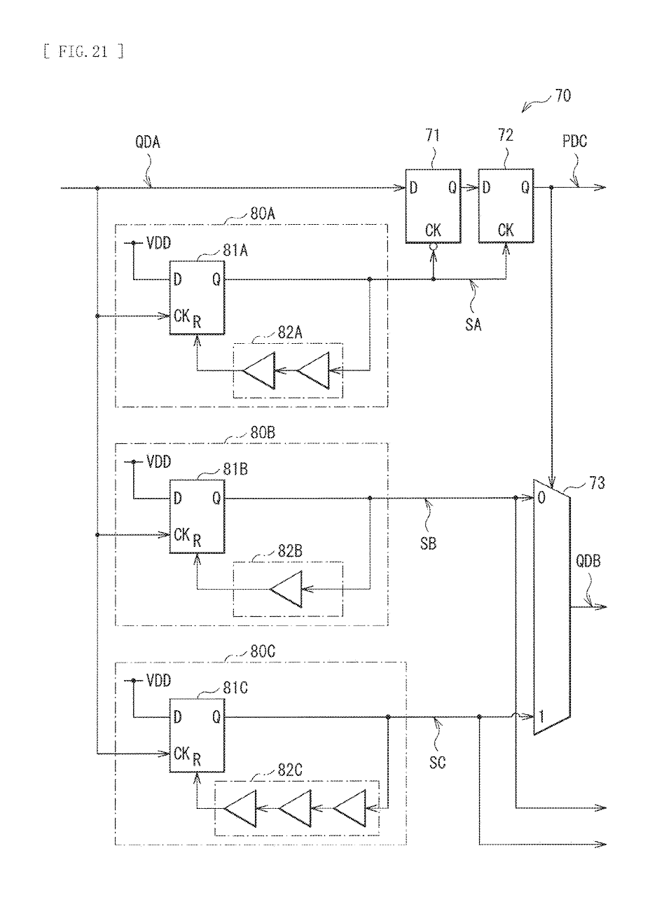

FIG. 20 illustrates a configuration example of the pixel Q. The pixel Q may include a buffer 61, a signal generator 62, and a controller 63. It is to be noted that description is given below referring to the first pixel Q(0) out of the N-number of pixels Q that are coupled to each other to form the daisy-chain connection for the sake of convenience in description. However, it is similarly applicable to other pixels Q(1) to Q(N−1). The pixel Q(0) may generate the data signal QD(1) on the basis of the data signal QD(0) inputted to an input terminal QDIN, and output the generated data signal QD(1) from an output terminal QDOUT.

The buffer 61 may perform waveform shaping on the data signal QD(0), and output the resulting signal as the data signal QDA.

The signal generator 70 may generate data signals PDC, QDB, SB, and SC on the basis of the data signal QDA.

FIG. 21 illustrates a configuration example of the signal generator 70. The signal generator 70 may include signal generating circuits 80A, 80B, and 80C, flip-flops 71 and 72, and a selector 73.

The signal generating circuit 80A may generate the data signal SA on the basis of the data signal QDA. The signal generating circuit 80A may include a flip-flop 81A and a delay circuit 82A. The flip-flop 81A may include a D flip-flop circuit. The flip-flop 81A may perform sampling of a signal at a high level (having a power source voltage VDD, in this example) on the basis of a rising edge of the data signal QDA, and output a result of the sampling as the data signal SA. The delay circuit 32A may delay the data signal SA by a time period “tdA” and output the delayed signal as a reset signal. The time period tdA may be about half the time corresponding to one period TCK of the clock signal CK(0). The signal generating circuit 80A may generate the data signal SA having a pulse width corresponding to the delay time period tdA of the delay circuit 82A on the basis of only rising of the data signal QDA, as with the clock generator 30 (FIGS. 6 and 7) according to the first embodiment.

Similarly, the signal generating circuit 80B may generate the data signal SB on the basis of the data signal QDA. The signal generating circuit 80B may include a flip-flop 81B and a delay circuit 82B. The signal generating circuit 80B may generate the data signal SB having a pulse width corresponding to a delay time period tdB of the delay circuit 82B on the basis of only rising of the data signal QDA. The delay time period tdB of the delay circuit 82B may be shorter than the delay time period tdA of the delay circuit 82A. The signal generating circuit 80B may supply this data signal SB to the selector 73 and to the selector 26A in the selector unit 26.

Similarly, the signal generating circuit 80C may generate the data signal SC on the basis of the data signal QDA. The signal generating circuit 80C may include a flip-flop 81C and a delay circuit 82C. The signal generating circuit 80C may generate the data signal SB having a pulse width corresponding to a delay time period tdC of the delay circuit 82C on the basis of only rising of the data signal QDA. The delay time period tdC of the delay circuit 82C may be longer than the delay time period tdA of the delay circuit 82A. The signal generating circuit 80C may supply this data signal SC to the selector 73 and to the selector 26A in the selector unit 26.

The flip-flop 71 may include a D flip-flop circuit. The flip-flop 71 may perform sampling of the data signal QDA on the basis of a falling edge of the data signal SA, and output a result thereof. The flip-flop 72 may include a D flip-flop circuit. The flip-flop 72 may perform sampling of the output signal of the flip-flop 71 on the basis of a rising edge of the data signal SA, and output a result thereof as the data signal PDC.

The selector 73 may select one of the data signals SB and SC on the basis of the data signal PDC, and output the selected signal as the data signal QDB. Specifically, the selector 73 may select the data signal SB and output the selected data signal SB as the data signal QDB, when the data signal PDC is at a low level. The selector 73 may select the data signal SC and output the selected data signal SC as the data signal QDB, when the data signal PDC is at a high level.

The controller 63 (FIG. 20) may serve as a state machine that sets a state of the pixel Q(0) and generates the signals LD, PLT, and CKEN, on the basis of the data signal PDC and the data signal QDA, as with the controller 23 according to the first embodiment. On this occasion, the controller 63 may use the data signal QDA as the clock signal.

In this example, the input terminal QDIN may correspond to one specific example of the “first input terminal” of the disclosure. The output terminal QDOUT may correspond to one specific example of the “first output terminal” of the disclosure. The signal generator 70 may correspond to one specific example of the “signal generator” of the disclosure. The controller 63 and the selector unit 26 may correspond to one specific example of the “controller” of the disclosure. The light emission unit 25 may correspond to one specific example of a “display device” of the disclosure.

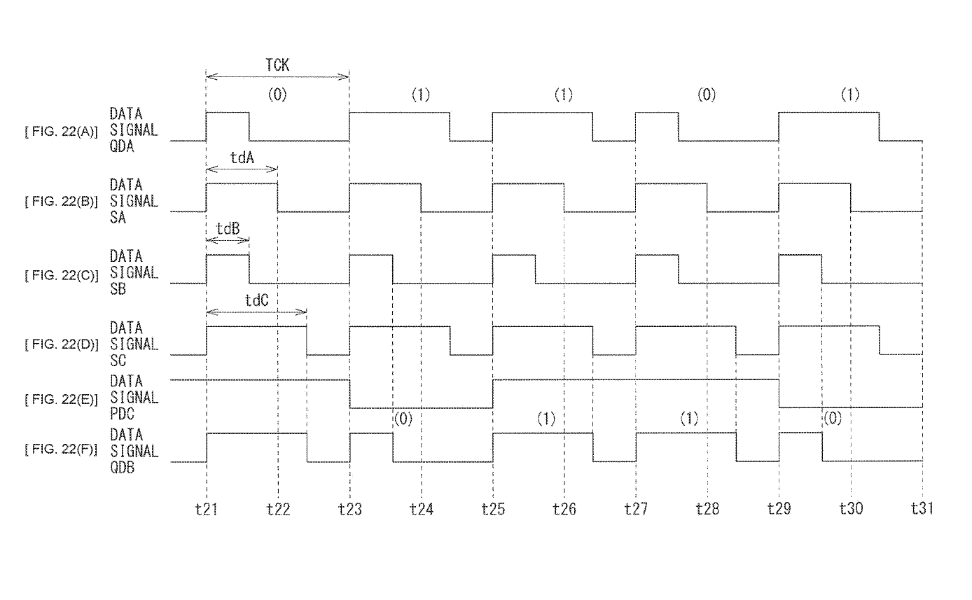

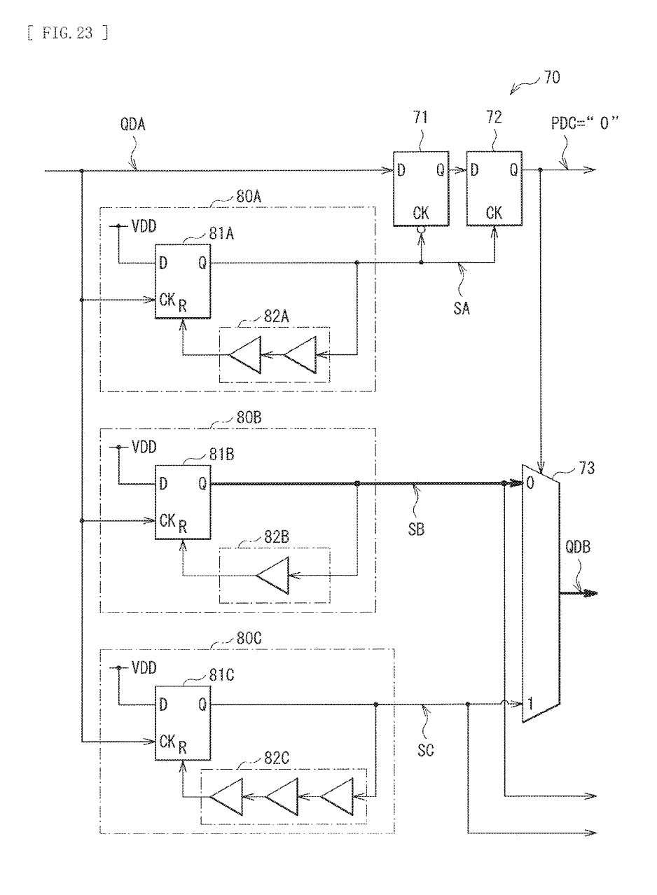

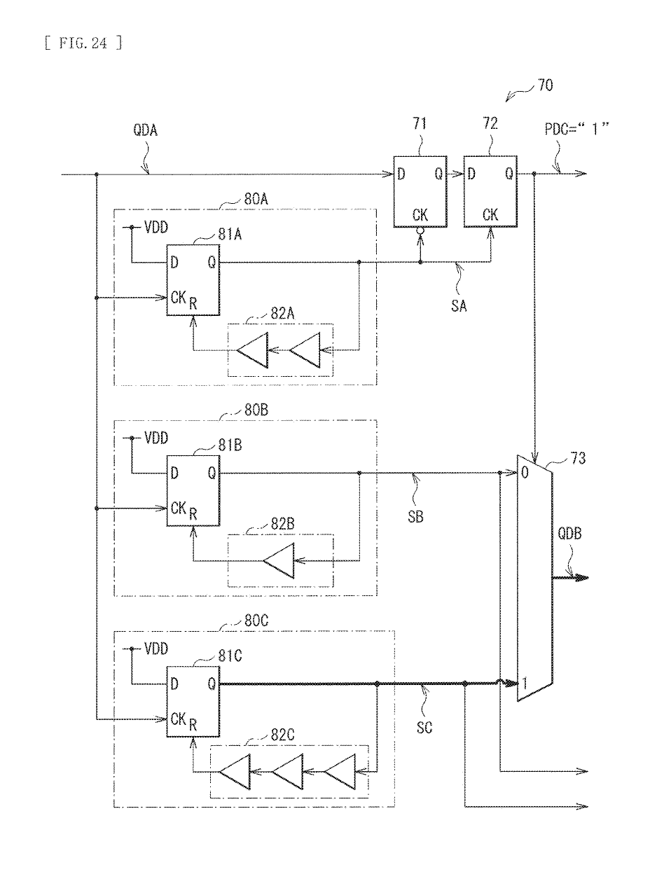

FIG. 22 illustrates an operation example of the signal generator 70. Part (A) illustrates a waveform of the data signal QDA, Parts (B) to (D) illustrate waveforms of the data signals SA to SC, respectively, Part (E) illustrates a waveform of the data signal PDC, and Part (F) illustrates a waveform of the data signal QDB. FIG. 23 illustrates one state of the signal generator 70, and FIG. 24 illustrates another state of the signal generator 70.

In this example, the data signal QDA may be inputted to the signal generator 70 in order of “0”, “1”, “1”, “0”, and “1” (Part (A) of FIG. 22). Specifically, the data signal QDA may indicate “0” in a period from timing t21 to timing t23, indicate “1” in a period from the timing t23 to timing t25, indicate “1” in a period from the timing t25 to timing t27, indicate “0” in a period from the timing t27 to timing t29, and indicate “1” in a period from the timing t29 to timing t31.

The signal generating circuits 80A to 80C may generate the data signals SA to SC, respectively, on the basis of this data signal QDA. Specifically, the signal generating circuit 80A may generate a pulse that starts from the rising edge of the data signal QDA and ends at timing the time period tdA after this edge (Part (B) of FIG. 22). The signal generating circuit 80B may generate a pulse that starts from the rising edge of the data signal QDA and ends at timing the time period tdB after this edge (Part (C) of FIG. 22). The signal generating circuit 80C may generate a pulse that starts from the rising edge of the data signal QDA and ends at timing the time period tdC after this edge (Part (D) of FIG. 22)

The flip-flop 71 may perform sampling of the data signal QDA at timing t22. Further, the flip-flop 72 may perform sampling of the output signal of this flip-flop 71 at the timing t23, and cause the data signal PDC to be at the low level on the basis of a result of the sampling (Part (E) of FIG. 22). The selector 73 may select the data signal SB and output the selected data signal SB as the data signal QDB in the period from the timing t23 to the timing t25 (FIG. 23).

Thereafter, the flip-flop 71 may perform sampling of the data signal QDA at timing t24. Further, the flip-flop 72 may perform sampling of the output signal of this flip-flop 71 at the timing t25, and cause the data signal PDC to be at the high level on the basis of a result of the sampling (Part (E) of FIG. 22). The selector 73 may select the data signal SC and output the selected data signal SC as the data signal QDB in the period from the timing t25 to the timing t27 (FIG. 24).

Thereafter, the flip-flop 71 may perform sampling of the data signal QDA at timing t26. Further, the flip-flop 72 may perform sampling of the output signal of this flip-flop 71 at the timing t27, and cause the data signal PDC to be at the high level on the basis of a result of the sampling (Part (E) of FIG. 22). The selector 73 may select the data signal SC and output the selected data signal SC as the data signal QDB in the period from the timing t27 to timing t29 (FIG. 24).

Thereafter, the flip-flop 71 may perform sampling of the data signal QDA at timing t28. Further, the flip-flop 72 may perform sampling of the output signal of this flip-flop 71 at the timing t29, and cause the data signal PDC to be at the low level on the basis of a result of the sampling (Part (E) of FIG. 22). The selector 73 may select the data signal SB and output the selected data signal SB as the data signal QDB in the period from the timing t29 to the timing t31 (FIG. 23).

The signal generator 70 may thus output the data signal QDB corresponding to the inputted data signal QDA (Part (F) of FIG. 22). On this occasion, the data signal QDB may be delayed from the data signal QDA by an amount corresponding to one period TCK of the data signal QDA, since the signal generator 70 incudes the flip-flops 71 and 72.

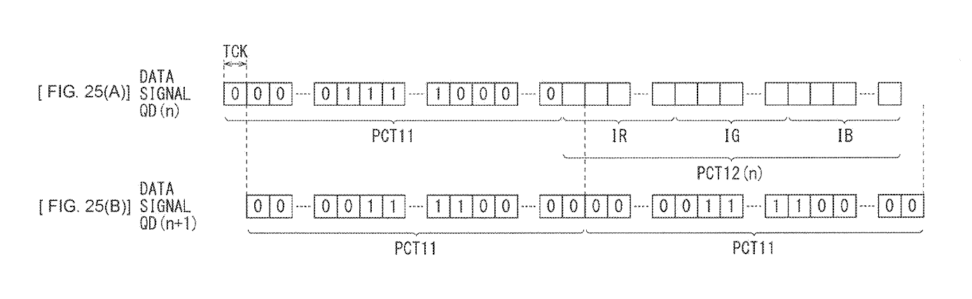

FIG. 25 illustrates an operation of reading the luminance data IR, IG, and IB by the n-th pixel Q(n). Part (A) illustrates the data signal QD(n) inputted to the pixel Q(n). Part (B) illustrates the data signal QD(n+1) outputted from the pixel Q(n).

The pixel Q(n−1) preceding the pixel Q(n) may supply the pixel Q(n) with the data signal QD(n) including the pilot packet PCT11 and the following pixel packet PCT12(n) (Part (A) of FIG. 25).

In the pixel Q(n), the buffer 61 may perform waveform shaping on the data signal QD(0), and output the resultant as the data signal QDA. Further, the signal generator 70 may generate the data signals PDC, QDB, SB, and SC on the basis of the data signal QDA. The controller 63 may determine, on the basis of the data pattern of the data signal PDC, that the pixel packet PCT12(n) is supplied after the pilot packet PCT11.

The controller 63 may supply the signals LD and PLT to the selector unit 26 in a period in which the data signal PDC indicates the pilot packet PCT11. The selector unit 26 may select the data signal QDB and output the selected data signal QDB as the data signal QD(n+1) (Part (B) of FIG. 25).

Further, the controller 63 may supply the signal CKEN to the memory unit 24 in a period in which the data signal PDC indicates the pixel packet PCT12(n) following the pilot packet PCT11. The memory unit 24 may read the luminance data IR, IG, and IB included in that pixel packet PCT12(n). Further, in this period, the controller 63 may supply the signals LD and PLT to the selector unit 26, and the selector unit 26 may generate the data signal QD(n+1) by replacing the pixel packet PCT12(n) included in the data signal QDB with the pilot packet PCT11 (Part (B) of FIG. 25).

The display panel 2 may represent the data (“0” or “1”) by varying the pulse width of the data signal QD as described above. This makes it possible to use the data signal QD as the data signal, and also use the data signal QD as the clock signal. This allows for a decrease in the number of signals between the pixels Q. It is therefore possible to reduce active devices such as a buffer in each of the pixels Q, and thereby to reduce power consumption. Moreover, thus reducing the number of signals between the pixels Q reduces the number of wirings in the display panel 2, resulting in less limitation upon performing of lay out of the display panel 2.

According to the present embodiment, the data (“0” or “1”) may be represented by varying the pulse width of the data signal QD as described above. It is therefore possible to reduce the number of signals between the pixels, resulting in reduction of power consumption. Further, thus reducing the number of signals between the pixels decreases limitation upon performing of lay out of the display panel. Other effects are similar to those of the first embodiment described above.

### [Modification 2-1]

According to the foregoing embodiment, the data signal QD may include two pulses having respective pulse widths that are different from each other as illustrated in FIG. 19. However, this is not limitative. The data signal QD may include three or more pulses having respective pulse widths that are different from each other. For example, in a case where the data signal includes four pulses having respective pulse widths that are different from each other, two bits may be transmittable by a single pulse.

### [Modification 2-2]

Each of the modifications of the first embodiment described above may be applied to the display panel 2 according to the foregoing embodiment.

The technology has been described above referring to some embodiments and the modifications thereof. However, the technology is not limited to the embodiments, etc. described above, and is modifiable in a variety of ways.

For example, the LED may be used as the display device in each of the embodiments, etc. described above. However, this is not limitative. Alternatively, an organic EL device may be used as the display device.

Moreover, the display panel according to each of the embodiments, etc. described above may be applied to various electronic apparatuses that display images such as a television apparatus, a laptop personal computer, and a smartphone. Moreover, the display panel according to each of the embodiments, etc. described above may be applied to a large-sized display that is provided, for example, in a soccer stadium or a baseball stadium.

It is to be noted that the effects described herein are mere examples and are non-limiting. Further, any other effect may be provided.

It is to be noted that the technology may have any of the following configurations.

(1) A pixel unit including:

a first input terminal;

a first output terminal;

a signal generator provided on a signal path extending from the first input terminal to the first output terminal, the signal generator generating a second signal on the basis of a first signal and outputting the generated second signal; and

a display device, in which

the signal generator generates a rising edge and a falling edge of the second signal on the basis of one of a rising edge and a falling edge of the first signal.

(2) The pixel unit according to (1), further including:

a second input terminal; and

a controller that controls the display device on the basis of a first data signal inputted to the second input terminal and one of the first signal and the second signal, in which

each of the first signal and the second signal is a clock signal.

(3) The pixel unit according to (2), in which the signal generator causes the second signal to make a transition at timing corresponding to timing of one of the rising edge and the falling edge of the first signal, and causes the second signal to make another transition at timing a predetermined time period after the timing at which the second signal has made the transition.
(4) The pixel unit according to (2) or (3), in which

the first data signal includes
a first packet having a predetermined data pattern and
a second packet following the first packet and having luminance data, and

the controller controls the display device on the basis of the second packet.

(5) The pixel unit according to (4), further including

a second output terminal, in which

the controller generates a second data signal by replacing, with the predetermined data pattern, a data pattern of the second packet included in the first data signal, and supplies the generated second data signal to the second output terminal.

(6) The pixel unit according to (1), further including

a controller that controls the display device on the basis of the first signal, in which

the first signal includes a plurality of pulses having respective pulse widths that are different from each other.

(7) The pixel unit according to (6), in which the signal generator causes the second signal to make a transition at timing corresponding to timing of one edge of the rising edge and the falling edge of the first signal, and causes the second signal to make another transition at timing a predetermined time period after the timing at which the second signal has made the transition, the predetermined time period being based on the pulse width of the pulse that starts from the one edge.
(8) The pixel unit according to (7), in which

each of pulse widths of the respective pulses is one of a first pulse width and a second pulse width, and

the signal generator
causes each of a third signal and a fourth signal to make a transition at the timing corresponding to the timing of the one edge,
causes the third signal to make another transition at timing a first time period after the timing at which the third signal has made the transition, the first time period corresponding to the first pulse width,
causes the fourth signal to make another transition at timing a second time period after the timing at which the fourth signal has made the transition, the second time period corresponding to the second pulse width,
selects and outputs the third signal as the second signal when the pulse width of the pulse that starts from the one edge is the first pulse width, and
selects and outputs the fourth signal as the second signal when the pulse width of the pulse that starts from the one edge is the second pulse width.
   (9) The pixel unit according to any one of (6) to (8), in which

the first signal includes
a first packet having a predetermined data pattern and
a second packet following the first packet and having luminance data, and

the controller controls the display device on the basis of the second packet.

(10) The pixel unit according to (9), in which the controller generates a fifth signal by replacing, with the predetermined data pattern, a data pattern of the second packet included in the second signal, and supplies the generated fifth signal to the first output terminal.
(11) A display panel including

one or a plurality of sets each including a plurality of pixel units, the pixel units being sequentially coupled to each other, the pixel units each including: a first input terminal; a first output terminal; a signal generator provided on a signal path extending from the first input terminal to the first output terminal, the signal generator generating a second signal on the basis of a first signal and outputting the generated second signal; and a display device, in which

the signal generator generates a rising edge and a falling edge of the second signal on the basis of one of a rising edge and a falling edge of the first signal.

(12) The display panel according to (11), further including a display driving unit that supplies a clock signal to the first input terminal of a first pixel unit out of the pixel units in each of the one or the plurality of sets.
(13) The display panel according to (11), further including a display driving unit that supplies a data signal to the first input terminal of a first pixel unit out of the pixel units in each of the one or the plurality of sets, the data signal including a plurality of pulses having respective pulse widths that are different from each other.
(14) A method of transmitting a signal, the method including:

causing a signal generator to cause a second signal to make a transition at timing corresponding to timing of one edge of a rising edge and a falling edge of a first signal, the signal generator being provided on a signal path extending from a first input terminal to a first output terminal of each of a plurality of signal processing units that are sequentially coupled to each other, the signal generator generating the second signal on the basis of the first signal; and

causing the signal generator to cause the second signal to make another transition at timing a predetermined time period after the timing at which the second signal has made the transition, the predetermined time period corresponding to a pulse width of a pulse that starts from the one edge.

This application is based upon and claims the benefit of priority of the Japanese Patent Application No. 2014-237817 filed in the Japan Patent Office on Nov. 25, 2014, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A pixel unit comprising:
a first input terminal;
a first output terminal;
a signal generator provided on a signal path extending from the first input terminal to the first output terminal, the signal generator generating a second signal on a basis of a first signal and outputting the generated second signal; and
a display device, wherein
the signal generator generates a rising edge and a falling edge of the second signal on a basis of one of a rising edge and a falling edge of the first signal.

2. The pixel unit according to claim 1, further comprising:
a second input terminal; and
a controller that controls the display device on a basis of a first data signal inputted to the second input terminal and one of the first signal and the second signal, wherein
each of the first signal and the second signal is a clock signal.

3. The pixel unit according to claim 2, wherein the signal generator causes the second signal to make a transition at timing corresponding to timing of one of the rising edge and the falling edge of the first signal, and causes the second signal to make another transition at timing a predetermined time period after the timing at which the second signal has made the transition.

4. The pixel unit according to claim 2, wherein
the first data signal includes
a first packet having a predetermined data pattern and
a second packet following the first packet and having luminance data, and
the controller controls the display device on a basis of the second packet.

5. The pixel unit according to claim 4, further comprising
a second output terminal, wherein
the controller generates a second data signal by replacing, with the predetermined data pattern, a data pattern of the second packet included in the first data signal, and supplies the generated second data signal to the second output terminal.

6. The pixel unit according to claim 1, further comprising
a controller that controls the display device on a basis of the first signal, wherein
the first signal includes a plurality of pulses having respective pulse widths that are different from each other.

7. The pixel unit according to claim 6, wherein the signal generator causes the second signal to make a transition at timing corresponding to timing of one edge of the rising edge and the falling edge of the first signal, and causes the second signal to make another transition at timing a predetermined time period after the timing at which the second signal has made the transition, the predetermined time period being based on the pulse width of the pulse that starts from the one edge.

8. The pixel unit according to claim 7, wherein
each of pulse widths of the respective pulses is one of a first pulse width and a second pulse width, and
the signal generator
causes each of a third signal and a fourth signal to make a transition at the timing corresponding to the timing of the one edge,
causes the third signal to make another transition at timing a first time period after the timing at which the third signal has made the transition, the first time period corresponding to the first pulse width,
causes the fourth signal to make another transition at timing a second time period after the timing at which the fourth signal has made the transition, the second time period corresponding to the second pulse width,
selects and outputs the third signal as the second signal when the pulse width of the pulse that starts from the one edge is the first pulse width, and
selects and outputs the fourth signal as the second signal when the pulse width of the pulse that starts from the one edge is the second pulse width.

9. The pixel unit according to claim 6, wherein
the first signal includes
a first packet having a predetermined data pattern and
a second packet following the first packet and having luminance data, and
the controller controls the display device on a basis of the second packet.

10. The pixel unit according to claim 9, wherein the controller generates a fifth signal by replacing, with the predetermined data pattern, a data pattern of the second packet included in the second signal, and supplies the generated fifth signal to the first output terminal.

11. A display panel comprising
one or a plurality of sets each including a plurality of pixel units, the pixel units being sequentially coupled to each other, the pixel units each including: a first input terminal; a first output terminal; a signal generator provided on a signal path extending from the first input terminal to the first output terminal, the signal generator generating a second signal on a basis of a first signal and outputting the generated second signal; and a display device, wherein
the signal generator generates a rising edge and a falling edge of the second signal on a basis of one of a rising edge and a falling edge of the first signal.

12. The display panel according to claim 11, further comprising a display driving unit that supplies a clock signal to the first input terminal of a first pixel unit out of the pixel units in each of the one or the plurality of sets.

13. The display panel according to claim 11, further comprising a display driving unit that supplies a data signal to the first input terminal of a first pixel unit out of the pixel units in each of the one or the plurality of sets, the data signal including a plurality of pulses having respective pulse widths that are different from each other.

14. A method of transmitting a signal, the method comprising:
causing a signal generator to cause a second signal to make a transition at timing corresponding to timing of one edge of a rising edge and a falling edge of a first signal, the signal generator being provided on a signal path extending from a first input terminal to a first output terminal of each of a plurality of signal processing units that are sequentially coupled to each other, the signal generator generating the second signal on a basis of the first signal; and
causing the signal generator to cause the second signal to make another transition at timing a predetermined time period after the timing at which the second signal has made the transition, the predetermined time period corresponding to a pulse width of a pulse that starts from the one edge.
